(19) United States
(12) Patent Application Publication
(10) Pub. No.: US 2012/0199067 A1
(43) Pub. Date: Aug. 9, 2012

(54) FILM-FORMING APPARATUS

(75) Inventors: Yuichiro MOROZUMI, Nirasaki City (JP); Izumi SATO, Oshu-shi (JP); Shinji ASARI, Oshu-shi (JP)

(73) Assignee: TOKYO ELECTRON LIMITED, Tokyo (JP)

(21) Appl. No.: 13/366,663

(22) Filed: Feb. 6, 2012

(30) Foreign Application Priority Data
Feb. 9, 2011 (JP) 2011-026400

(51) Int. Cl. C23C 16/455

(52) U.S. Cl. 118/719

(57) ABSTRACT

An atmosphere in a reaction pipe is replaced by supplying a purge gas into the reaction pipe from a slit of a third gas injector when process gases are switched, by providing the third gas injector including the slit along a length direction of the reaction pipe in addition to first and second gas injectors including gas ejection holes for respectively supplying process gases, such as s Zr-based gas and an O₃ gas, into the reaction pipe.

### CROSS-REFERENCE TO RELATED PATENT APPLICATIONS

This application claims the benefit of Japanese Patent Application No. 2011-026400, filed on Feb. 9, 2011 in the Japan Patent Office, the disclosure of which is incorporated herein in its entirety by reference.

### BACKGROUND OF THE INVENTION

1. Field of the Invention

The present invention relates to a film-forming apparatus which carries a substrate holding unit holding a plurality of substrates in a shelf shape into a vertical reaction pipe where a heating unit is provided around the vertical reaction pipe, and performs a film-forming process on the substrates.

2. Description of the Related Art

An atomic layer deposition (ALD) method is well known as a method of forming a thin film. The ALD method sequentially (alternately) supplies a plurality of process gases, for example, two types of process gases that react with each other, to a substrate, such as a semiconductor wafer (hereinafter, referred to as a wafer), and deposits reaction products. When the ALD method is performed in a vertical heat processing apparatus, an injector for supplying a first process gas and an injector for supplying a second process gas are used, where the injectors are provided as so-called distribution injectors having gas ejection holes on locations corresponding to each of wafers. Also, when a process gas is switched, a purge gas is supplied from, for example, these two injectors.

Meanwhile, a semiconductor device having a 3D structure is being studied, and in detail, for example, a film-forming process may be performed on a surface of a wafer having a plurality of openings, by using the above-described ALD method, where an aspect ratio of a depth measurement and an opening diameter of the openings is high and the depth measurement and the opening diameter are respectively about 30 nm and about 2000 nm. A surface area of such a wafer may be, for example, 40 to 80 times larger than that of a flat wafer. Thus, it may be difficult to exhaust (replace) a process gas physically adsorbed on a surface of a wafer at a flow rate of a purge gas supplied from an above-described injector. Accordingly, for example, since process gases are mixed together under a process atmosphere (in a reaction pipe), i.e., react with each other in terms of chemical vapor deposition (CVD), a film thickness of a thin film is greater at a top than on a bottom of an above-described opening, and thus satisfactory coverage (coating) cannot be obtained, for example, an upper portion of the opening may be blocked.

Patent Reference 1 discloses a technology of supplying an inert gas from inert gas ejection holes 24c and 24d of inert gas nozzles 22c and 22d to a wafer 10 so as to limit flow of a process gas during a film-forming process, and Patent Reference 2 discloses a method of forming a thin film by using an ALD method in a vertical heat processing apparatus, but the above problems are not studied.

3. Prior Art Reference
(Patent Reference 1) Japanese Patent Laid-Open Publication No. 2010-118462 (paragraphs 0048 and 0051)
(Patent Reference 2) Japanese Patent Laid-Open Publication No. 2005-259841 (paragraph 0019)

### SUMMARY OF THE INVENTION

The present invention provides a film-forming apparatus for easily replacing atmosphere while switching a process gas, when a film-forming process is performed by sequentially supplying a plurality of types of process gases that react with each other on a plurality of substrates that are held in a shelf shape in a substrate holding unit.

According to an aspect of the present invention, a film-forming apparatus carries a substrate holding unit holding a plurality of substrates in a shelf shape into a vertical reaction pipe around which a heating unit is provided, and performs a film-forming process on the substrates, the film-forming apparatus including:

a first gas injector which includes a plurality of gas ejection holes each provided on height locations between the substrates to supply a first process gas to the substrates;

a second gas injector which is provided to be spaced apart from the first gas injector along a circumferential direction of the reaction pipe, is extended along a length direction of the reaction pipe, and includes a plurality of gas ejection holes provided toward the substrates, so as to supply a second process gas that reacts with the first process gas to the substrates;

a third gas injector which is provided to extend along the length direction of the reaction pipe on a location spaced apart from the first gas injector along the circumferential direction of the reaction pipe, and includes a slit for supplying a purge gas from an upper end to a lower end of a holding region of the substrate holding unit holding the substrates;

an exhaust hole which is provided on a side opposite to the first gas injector by interposing the holding region between the first gas injector and the exhaust hole, and for evacuating an atmosphere in the reaction pipe; and

a controller which outputs a control signal to replace the atmosphere in the reaction pipe by sequentially supplying the first process gas and the second process gas into the reaction pipe and supplying the purge gas into the reaction pipe while switching the first and second process gases.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a longitudinal-sectional view of a vertical heat processing apparatus according to an embodiment of the present invention;

FIG. 2 is a cross-sectional plan view of the vertical heat processing apparatus;

FIG. 3 is a lateral view schematically showing each of gas injectors of the vertical heat processing apparatus;

FIG. 4 is a top cross-sectional view of one of the gas injectors;

FIG. 5 is a cross-sectional plan view showing steps in the vertical heat processing apparatus;

FIG. 6 is a cross-sectional plan view showing steps in the vertical heat processing apparatus;

FIG. 7 is a cross-sectional plan view showing steps in the vertical heat processing apparatus;

FIG. 8 is a schematic view of a gas injector according to another embodiment of the present invention;

FIG. 9 is a schematic view of a gas injector according to another embodiment of the present invention;

FIG. 10 is a schematic view of a gas injector according to another embodiment of the present invention;

FIG. 11 is a cross-sectional plan view of the vertical heat processing apparatus according to another embodiment of the present invention;

FIG. 12 is a longitudinal-sectional view of the vertical heat processing apparatus according to another embodiment of the present invention;

FIG. 13 is a perspective view of a reaction pipe of the vertical heat processing apparatus according to the other embodiment of the present invention;

FIG. 14 is a diagram showing characteristics obtained according to an example of the present invention; and

FIG. 15 is a longitudinal-sectional view schematically showing a wafer used in the example.

### DETAILED DESCRIPTION OF THE INVENTION

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

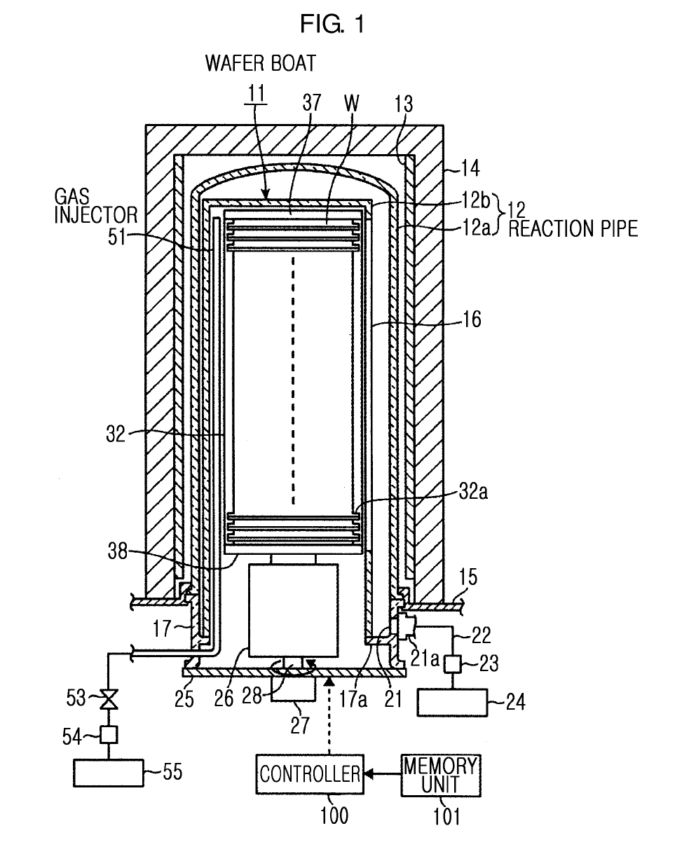

A film-forming apparatus according to an embodiment of the present invention will be described with reference to FIGS. 1 through 4. First, the film-forming apparatus is briefly described. The film-forming apparatus is configured as a vertical heat processing apparatus which forms a thin film according to an atomic layer deposition (ALD) method that deposits reaction products by sequentially (alternately) supplying a plurality of process gases, in this case, two types of process gases that react with each other, to a wafer W. Also, the film-forming apparatus is configured to supply an inert gas as a purge gas at a flow rate higher than those of the process gases while switching the process gases, and quickly replace a process atmosphere to perform a film-forming process. Hereinafter, a detailed structure of the film-forming apparatus is described.

The film-forming apparatus includes a wafer boat 11 constituting a substrate holding unit formed of, for example, quartz, to hold wafers W having a diameter size of, for example, 300 mm, in a shelf shape, and a reaction pipe 12 formed of, for example, quartz, to perform a film-forming process by airtightly holding the wafer boat 11 therein. A heating furnace body 14 to which a heater 13 constituting a heating unit is provided throughout a circumferential direction of an inner wall surface of the heating furnace body 14 is provided on an outer side of the reaction pipe 12, and lower portions of the reaction pipe 12 and the heating furnace body 14 are supported throughout the circumferential direction by a base plate 15 extended in a horizontal direction. A plurality of supports 32, for example, three supports 32, extended in an up-and-down direction are provided on the wafer boat 11, and a groove portion 32a for supporting the bottom of the wafer W is provided on an inner circumference of each support 32 at a holding location of each of a plurality of the wafers W. Also, in FIG. 1, a reference numeral 37 denotes a top plate of the wafer boat 11 and a reference numeral 38 denotes a bottom plate of the wafer boat 11.

In this embodiment, the reaction pipe 12 has a double pipe structure of an outer pipe 12a and an inner pipe 12b accommodated in the outer pipe 12a, wherein bottom surfaces of the outer pipe 12a and inner pipe 12b are each open. A top surface of the inner pipe 12b is horizontal, and a top surface of the outer pipe 12a has an approximate cylindrical shape to outwardly protrude. The outer pipe 12a and the inner pipe 12b are airtightly supported from the bottom thereof by a flange unit 17 having an approximate cylindrical shape of which a lower end surface has a flange shape while top and bottom surfaces thereof are open. In other words, the outer pipe 12a is airtightly supported by an upper end surface of the flange unit 17, and the inner pipe 12b is airtightly supported by a protrusion portion 17a horizontally protruded from an inner wall surface of the flange unit 17 to an inner side of the flange unit 17. A portion of a side surface of the inner pipe 12b is provided to outwardly protrude along a length direction of the inner pipe 12b, and a gas injector 51 is accommodated at the portion protruded outwardly.

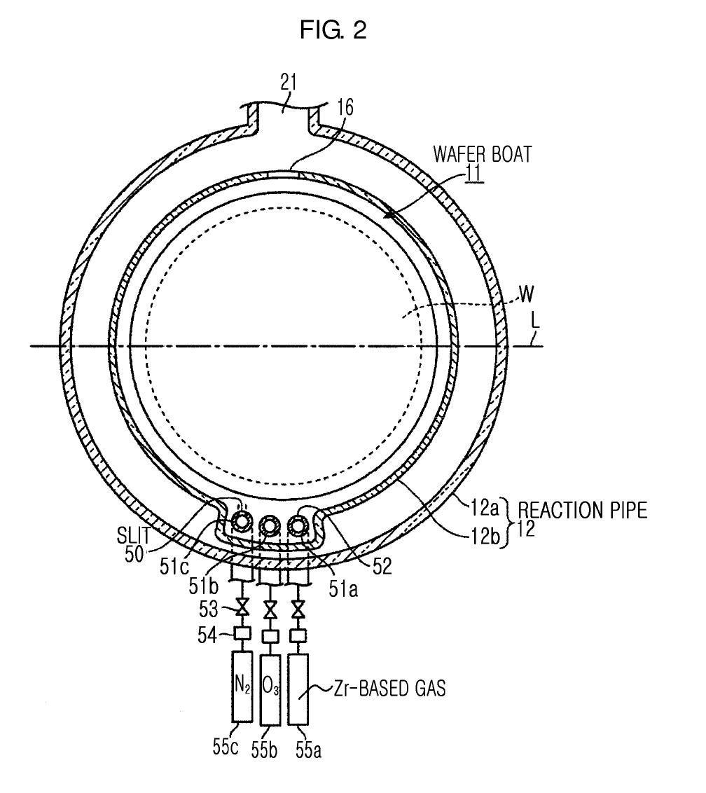

In this embodiment, three gas injectors 51 are provided, wherein the gas injectors 51 are each provided along a length direction of the wafer boat 11 while being spaced apart from each other along a circumferential direction of the reaction pipe 12. The gas injectors 51 are each formed of, for example, quartz. As shown in FIG. 2, if the three gas injectors 51 are called a first gas injector 51a, a second gas injector 51b, and a third gas injector 51c in a clockwise rotation (right turn) from the top of the reaction pipe 12, a storage source 55a of a Zr-based gas (material gas) including zirconium (Zr), for example, a tetrakisethylmethylaminozirconium (TEMAZr) gas, is connected to the first gas injector 51a. Also, a storage source 55b of an ozone (O₃) gas is connected to the second gas injector 51b, and a storage source 55c of a nitrogen (N₂) gas is connected to the third gas injector 51c. In FIG. 2, a reference numeral 53 denotes a valve and a reference numeral 54 denotes a flow rate adjusting unit.

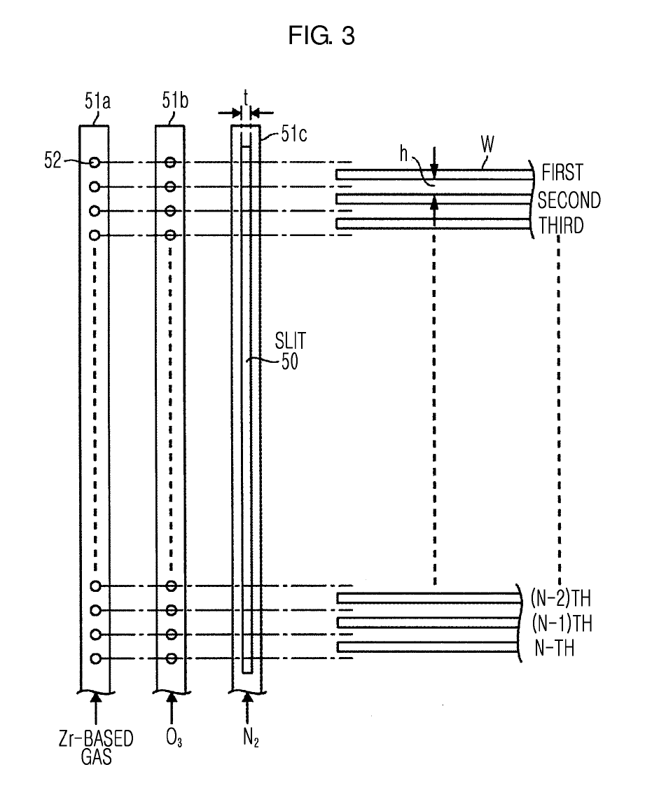

As shown in FIG. 3, a plurality of gas ejection holes 52 are provided at equal intervals along an up-and-down direction of each of the first and second gas injectors 51a and 51b on a pipe wall corresponding to a holding region (process region) of the wafer W, wherein an opening diameter of each gas ejection hole 52 is, for example, 0.5 mm. Also, each gas ejection hole 52 is provided to correspond to a holding location of each wafer W on the wafer boat 11, i.e., to face a region between a top surface of one wafer W and a bottom surface of another wafer W facing the top of the one wafer W. Also, FIG. 3 shows each gas injector 51 viewed from a side of the wafers W, wherein each wafer W is illustrated to be not laterally aligned with the gas injector 51. Also, the wafer boat 11 and the reaction pipe 12 are not shown in FIG. 3.

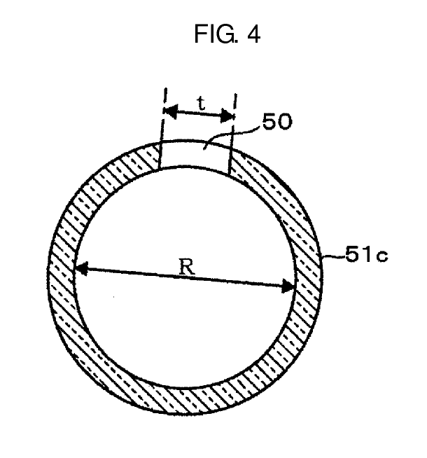

Also, a slit 50 having an approximate rectangular shape is provided to extend in an up-and-down direction from an upper end to a lower end of the holding region, on a pipe wall of the third gas injector 51c corresponding to the holding region. In other words, when a number of wafers W held by the wafer boat 11 is N, the slit 50 is extended from a location above a surface of a wafer W (first wafer W) at an upper end in the holding region to a location below a bottom surface of a wafer W (N-th wafer) at a lower end in the holding region. As shown in FIG. 4, a width size t of the slit 50 (in detail, a width size along a circumferential direction of an outer circumference surface of the third gas injector 51c) is from 0.01 to 1 mm, and in this embodiment, the width size t is 0.3 mm. Also, when the third gas injector 51c is viewed in plane, an inner diameter size R of a path of the purge gas (inner diameter of a pipe body) is, for example, 11.4 mm. Here, as shown in FIG. 3, an interval h between adjacent wafers W is, for example, 11 mm.

An exhaust hole 16 having a slit shape is provided on the side surface of the inner pipe 12b described above to face each gas injector 51, along the length direction of the inner pipe 12b, as shown in FIG. 2. In other words, the exhaust hole 16 is provided on a side opposite to each gas injector 51 by interposing the holding region of the wafer boat 11, where the wafer W is held between the exhaust hole 16 and each gas injector 51, in the present embodiment, to face each gas injector 51. An upper end location and a lower end location of the exhaust hole 16 are provided to have the same height locations as an upper end location and a lower end location of the slit 50 of the third gas injector 51c. Accordingly, the process gases and purge gas supplied to the inner pipe 12b from each of the gas injectors 51 are exhausted to a region between the inner pipe 12b and the outer pipe 12a via the exhaust hole 16. Here, if L denotes a straight line that is parallel to the first and third gas injectors 51a and 51c and passes through a center of the reaction pipe 12 when the reaction pipe 12 is viewed from the top, the opposite side denotes a region where the gas injectors 51 are not provided, from among two regions in the reaction pipe 12 defined by the straight line L, as shown in FIG. 2.

Also, an exhaust hole 21 is provided on a side wall of the flange unit 17 described above to communicate with a region between the inner pipe 12b and the outer pipe 12a, and a vacuum pump 24 is connected to an exhaust path 22 extended from the exhaust hole 21 by interposing a pressure adjusting unit 23, such as a butterfly valve, between the exhaust path 22 and the vacuum pump 24. A cover body 25 having an approximate circular plate shape is provided on a lower portion of the flange unit 17 such that an outer edge portion of the cover body 25 airtightly contacts a flange surface constituting the lower portion of the flange unit 17 throughout a circumferential direction, wherein the cover body 25 is configured to freely elevate with the wafer boat 11, by an elevating mechanism (not shown), such as a boat elevator. In FIG. 1, a reference numeral 26 denotes a insulating body having a cylindrical shape between the wafer boat 11 and the cover body 25, and a reference numeral 27 denotes a rotating mechanism, such as a motor, to rotate the wafer boat 11 and the insulating body 26 around a vertical axis. Also, in FIG. 1, a reference numeral 28 denotes a rotating shaft that connects the motor 27 to the wafer boat 11 and the insulating body 26 by airtightly penetrating through the cover body 25, and a reference numeral 21a denotes an exhaust port.

A controller 100 including a computer to control operations of the whole apparatus is provided in the vertical heat processing apparatus, and a program for performing a film-forming process described later is stored in a memory of the controller 100. The program is installed in the controller 100 from a memory unit 101 constituting a memory medium, such as a hard disk, a compact disk, a magneto-optical disk, a memory card, or a flexible disk.

Next, steps of the above embodiment are described. First, 150 wafers W, for example, having a size of 12 inches (300 mm) are placed on the wafer boat 11 by using a transfer arm (not shown), in the bottom of the reaction pipe 12. A hole for embedding, for example, a high dielectric substance is provided on a surface of each wafer W. In the wafer boat 11, dummy wafers are held from the uppermost end (first) wafer to fifth wafer and from the lowermost end (N-th) wafer to (N−4)th wafer, and the wafers W for products are held between the dummy wafers (a space between sixth wafer to (N−5)th wafer).

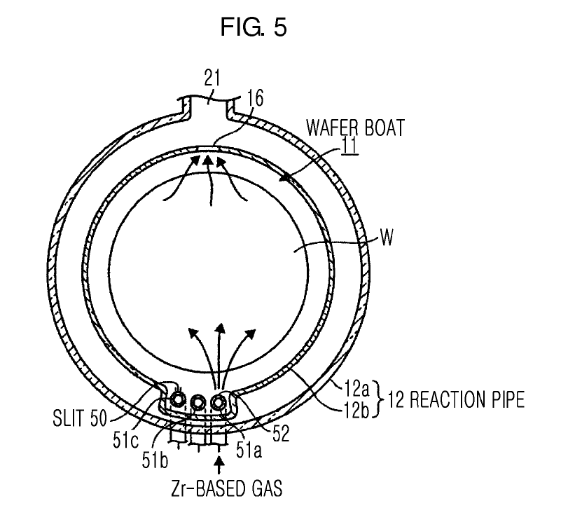

Also, the wafer boat 11 is airtightly inserted into the reaction pipe 12, and the wafer W on the wafer boat 11 is heated up to, for example, 250° C., by using the heater 13 while vacuum-exhausting an atmosphere in the reaction pipe 12 by using the vacuum pump 24 and rotating the wafer boat 11 around the vertical axis. Then, a pressure inside the reaction pipe 12 is adjusted to a process pressure, for example, 1.0 Torr (133 Pa), by using the pressure adjusting unit 23 while supplying the Zr-based gas described above constituting a first process gas from the gas ejection holes 52 of the first gas injector 51a into the reaction pipe 12 as shown in FIG. 5, at, for example, 0.4 ml/min (liquid flow rate). When the Zr-based gas contacts a surface of the wafer W, an atomic layer or molecular layer of the Zr-based gas is adsorbed on the surface of the wafer W. An unreacted Zr-based gas or an organic gas or the like generated due to adsorption on the wafer W is exhausted through the exhaust hole 16.

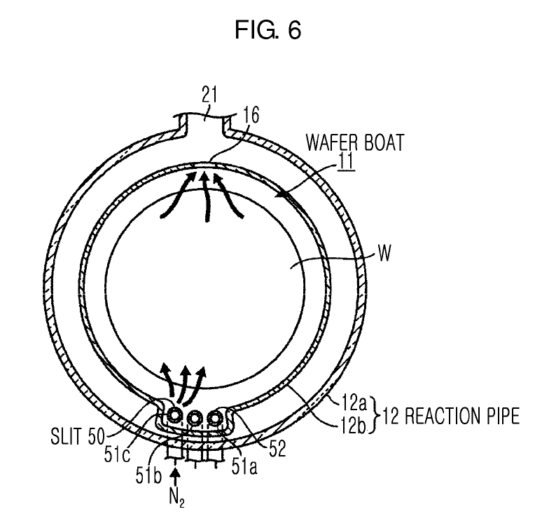

Next, when the supply of the Zr-based gas is stopped and the 150 wafers W having the size of, for example, 12 inches are held by the wafer boat 11, it is preferable to supply the N₂ gas constituting the purge gas from the third gas injector 51c into the reaction pipe 12 at 20 slm (liter/min) to 100 slm as shown in FIG. 6, and in this embodiment, the N₂ gas is supplied at 60 slm for, for example, 20 seconds. As such, since the purge gas having a flow rate higher than the flow rate of the Zr-based gas is supplied into the reaction pipe 12, the atmosphere in the reaction pipe 12 is very quickly replaced.

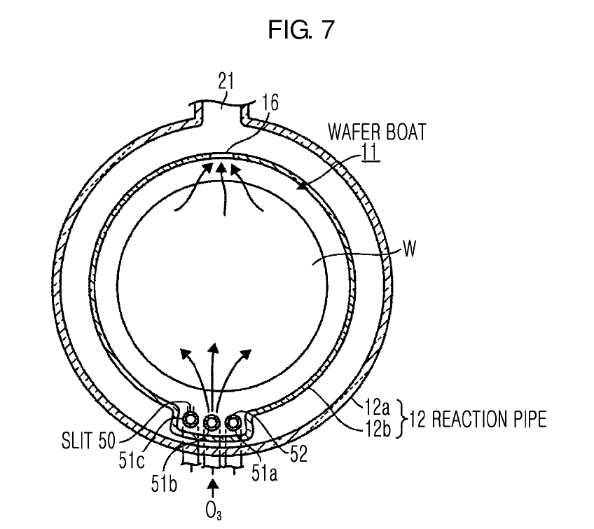

Next, the supply of the purge gas is stopped, and the O₃ gas constituting a second process gas is supplied into the reaction pipe 12 as shown in FIG. 7, at, for example, 300 g/Nm³ (concentration of O₃ obtained by flowing O₂ at 20 slm). The O₃ gas flows toward the wafer W from each of the gas ejection holes 52 of the second gas injector 51b, and generates reaction products formed of zirconium oxide (Zr—O) by oxidizing components of the Zr-based gas adsorbed on each wafer W. Then, after stopping the supply of the O₃ gas, the atmosphere of the reaction pipe 12 is replaced by using the purge gas as described above. As such, layers of the reaction products are deposited on each other by performing a plurality of supply cycles where the Zr-based gas, the purge gas, the O₃ gas, and the purge gas are supplied in the stated order.

According to the above embodiment, when the reaction products are deposited according to an ALD method by alternately supplying two types of process gases that react with each other to the wafer W, the third gas injector 51c is provided separately from the first gas injector 51a for supplying a process gas, and the purge gas is supplied from the slit 50 provided along a length direction of the third gas injector 51c while switching the process gases. Also, the flow rate of the purge gas is set to be a high flow rate, for example, 40 times higher than, for example, that in a conventional apparatus (when the purge gas is supplied by using the gas injector 51 including the gas ejection holes 52). Accordingly, since the purge gas is stably supplied (for example, without damaging the third gas injector 51c or the like) into the reaction pipe 12 at a flow rate much higher than the flow rate of a process gas while switching the process gases, the atmosphere in the reaction pipe 12 can be quickly replaced. Thus, since, for example, a CVD reaction between the process gases under a process atmosphere can be suppressed, a film-forming process having a satisfactory coating (coverage) property throughout the surface of the wafer W and having highly uniform film thickness and film quality can be performed even on the wafer W having a 3D structure (having high surface area), as described in a following embodiment.

Also, in the third gas injector 51c for supplying the purge gas, since the slit 50 is provided throughout the upper portion to the lower portion of the third gas injector 51c, the purge gas can be supplied to each wafer W in a laminar flow state by suppressing generation of, for example, turbulence. Accordingly, the purge gas can be supplied to the holding region of the wafer W without non-uniformity or while non-uniformity is suppressed, and for example, generation of particles due to detachment or the like of a CVD film deposited on the pipe wall (periphery portion of the slit 50) of the third gas injector 51c can be suppressed. Also, since the width size t of the slit 50 is set within the above-described range, the purge gas can be supplied at a similar flow rate along a length direction of the slit 50.

Also, since the flow rate of the purge gas is set to be higher than the flow rate of each process gas as described above while suppressing the process gases from being mixed with each other when the process gases are switched, an inside of the reaction pipe 12 may not be under a high-degree vacuum as described in the following embodiment. In other words, since the pressure inside the reaction pipe 12 can be set to the process pressure suitable for the film-forming process, the film-forming process can be performed while suppressing decrease of a film-forming rate.

Here, the gas ejection holes 52 for supplying a process gas are provided on the first gas injector 51a, and a flow rate of the process gas is minimized. In other words, it is not a profitable plan in terms of high expenses for the process gas (material gas) if the process gas is to be uniformly supplied from the slit 50 to a region between the wafers W, since the flow rate of the process gas is increased more than necessary. However, in the present invention, the flow rate of the Zr-based gas constituting a material gas is reduced by providing the gas ejection holes 52 on the first gas injector 51a meanwhile the slit 50 is provided on the third gas injector 51c so that the purge gas is supplied at a high flow rate, thereby adjusting gas ejection regions (gas ejection holes 52 and slit 50) according to the flow rates of each gas. Also, the flow rate of the O₃ gas is reduced (optimized) by providing the exclusive second gas injector 51b separately from the third gas injector 51c for a high flow rate. Thus, the film-forming according to an ALD method can be quickly performed while suppressing expenses of the process gas (material gas or O₃ gas).

The above-described slit 50 may have a tapered shape in an up-and-down direction, and in detail, the width size t of the upper end and the width size t of the lower end of the slit 50 may be respectively set to 4 mm and 1 mm, and angles between the vertical axis and two outer edges extended in the up-and-down direction from among four outer edges of the slit 50 may be each set to 1°.

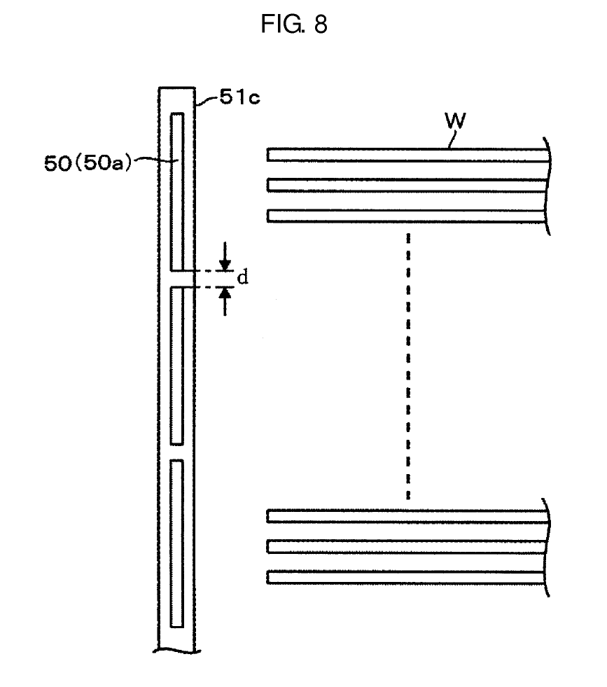

Also, the slit 50 may be divided into a plurality of numbers along the length direction thereof. FIG. 8 shows an embodiment of the slit 50 divided into three at equal intervals along the length direction thereof. In this embodiment, when a reference numeral 50a denotes each of the three slits 50, distances d between adjacent slits 50a are, for example, set to about 0.05 cm to 1.0 cm (size identical to a thickness size of the wafer W).

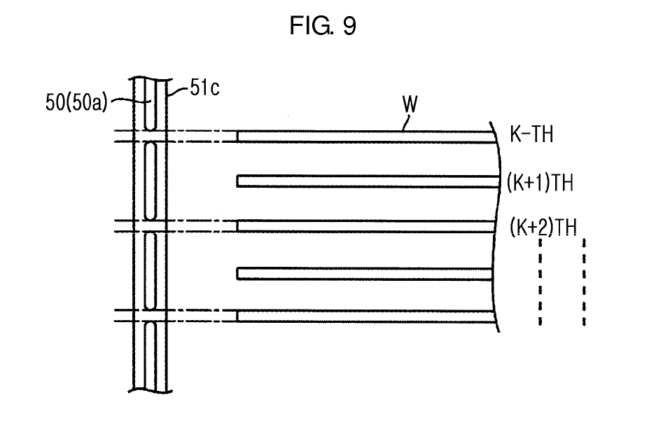

Also, FIG. 9 shows an embodiment of the slits 50a having the shortest length size, i.e., an embodiment of the slit 50 divided the highest number of times. In detail, each slit 50a is common to two adjacent wafers W, and is provided from a lower end location of a k-th wafer W to an upper end location of a (k+2)th wafer W below the k-th wafer W, wherein k is a natural number. Even in FIG. 9, the distances d have the same size. Also, FIG. 9 shows an enlarged part of the third gas injector 51c.

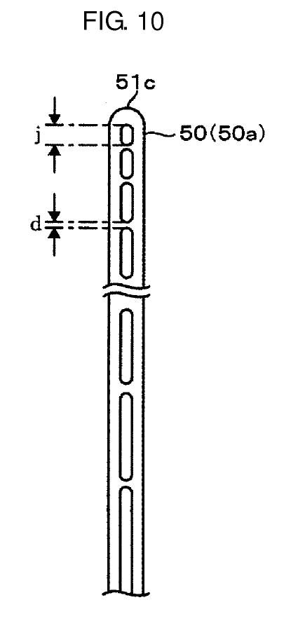

Also, FIG. 10 shows the third gas injector 51c according to another embodiment. In FIG. 10, the plurality of slits 50a are provided along the length direction of the third gas injector 51c, like as in FIGS. 8 and 9. Also, in this embodiment, length sizes j of the slits 50a are gradually increased from the top to the bottom of the third gas injector 51c. In detail, the length sizes j of the slits 50a at the upper end and the lower end of the third gas injector 51c are respectively, for example, 1.6 cm and 12 cm, and increase by, for example, 0.8 cm from the upper end to the lower end.

In other words, since the purge gas is supplied from the bottom of the third gas injector 51c, the flow rate of the purge gas flowing inside of the third gas injector 51c decreases from the bottom to the top of the third gas injector 51c. Accordingly, in this embodiment, the length sizes j of the slits 50a are set to be long in the bottom where the flow rate of the purge gas is high and to gradually decrease toward the top where the flow rate of the purge gas is decreased, according to the flow rate of the purge gas flowing inside of the third gas injector 51c. Thus, the purge gas supplied from each slit 50a to the wafer W along the length direction of the third gas injector 51c may be supplied at a similar pressure. In this embodiment, the distances d between adjacent slits 50a are also the same, as described above.

Here, as described above, since the purge gas is supplied from the bottom of the third gas injector 51c, the purge gas may be excessively supplied to the wafer W at the bottom of the third gas injector 51c, whereas the flow rate of the purge gas to the wafer W at the top of the third gas injector 51c may not be sufficient. In this case, in the slits 50a, the length sizes j may be set to be short at the bottom and to gradually increase toward the top of the third gas injector 51c, i.e., the arrangement of the slits 50a in FIG. 10 may be reversed.

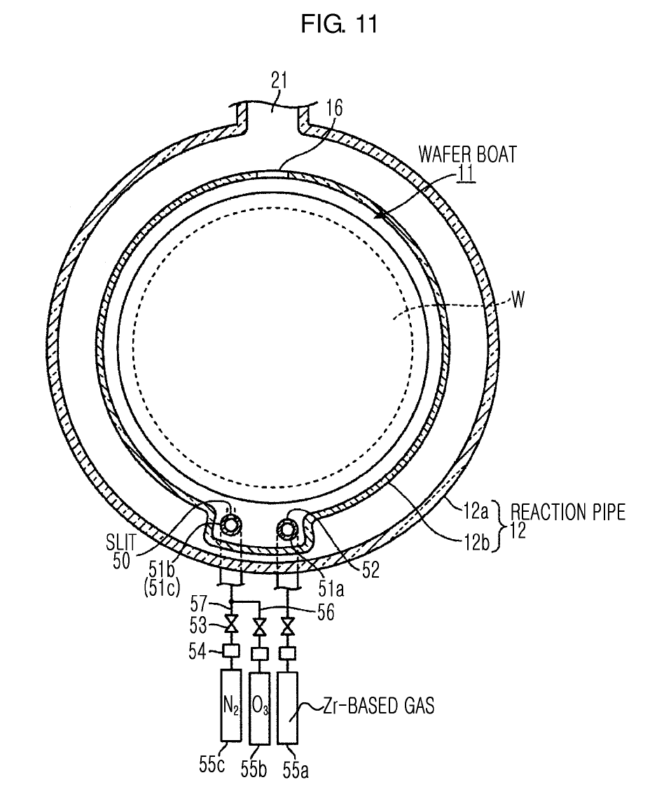

Here, as described above, since the flow rate of the O₃ gas is higher than the flow rate of the Zr-based gas, the O₃ gas may be supplied into the reaction pipe 12 from the third gas injector 51c, which supplies the N₂ gas. In other words, the second gas injector 51b for supplying the O₃ gas and the third gas injector 51c for supplying the N₂ gas may be commonly used, as shown in FIG. 11. In FIG. 11, a gas supply path 56 extended from a storage source 55b of O₃ gas is connected to a gas supply path 57 between a storage source 55c of N₂ gas and the third gas injector 51c on the outer region of the reaction pipe 12.

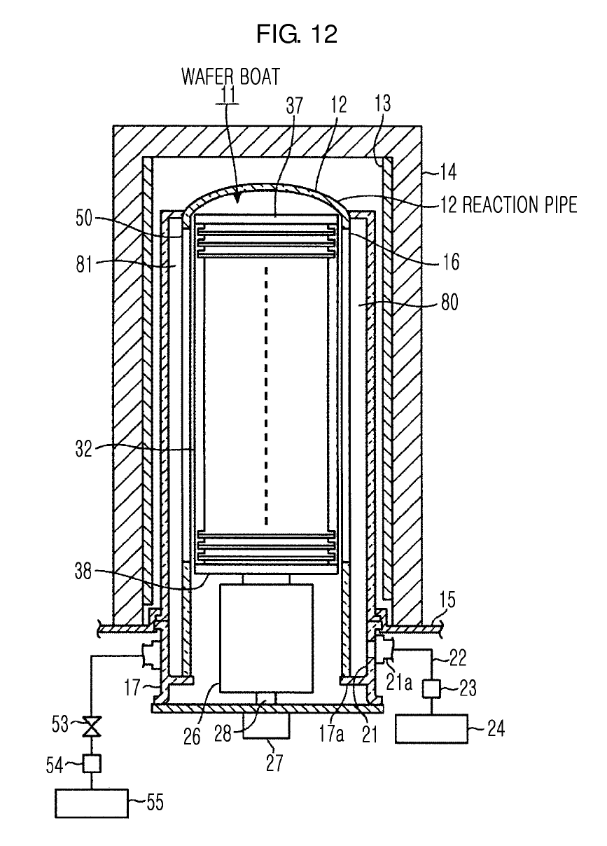

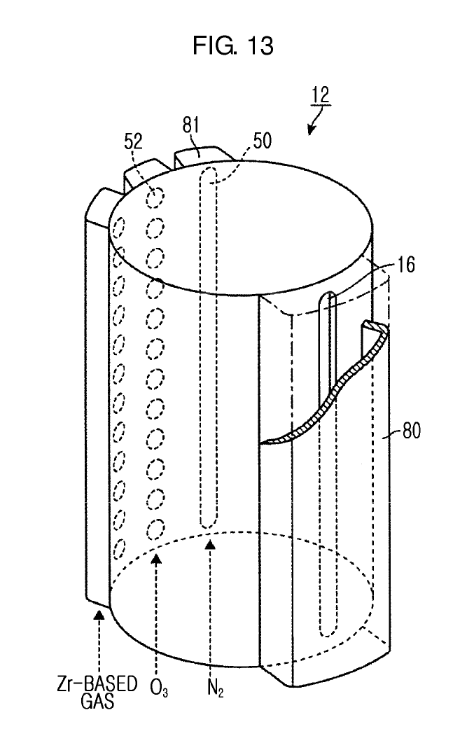

Also, the reaction pipe 12 has a double pipe structure, but alternatively, the reaction pipe 12 having a single pipe structure may be used while a gas supply unit (gas injector) and an exhaust unit each having a duct shape and extended in the length direction of the wafer boat 11 may be airtightly provided outside of the reaction pipe 12, and the gas ejection holes 52, the slit 50, and the exhaust hole 16 may be provided on the side surface of the reaction pipe 12 to each communicate with the gas supply unit and the exhaust unit. FIGS. 12 and 13 show major elements of such an example. In FIGS. 12 and 13, a reference numeral 80 denotes an exhaust duct and a reference numeral 81 denotes a gas supply unit, wherein the gas supply unit 81 is individually provided for the Zr-based gas, the O₃ gas, and the N₂ gas. Also, FIG. 13 shows the exhaust hole 16 inside the exhaust duct 80 provided by cutting out a part of the exhaust duct 80.

In the above embodiment, the flow rate of the N₂ gas supplied from the third gas injector 51c to the reaction pipe 12 is set to 20 slm to 100 slm, but if the number of wafers W held by the wafer boat 11 is N, the flow rate of the N₂ gas may be set to 0.05N slm to 2.0N slm, and in detail, 7.5 slm to 300 slm (when a held number of wafers W is 150)

### Examples

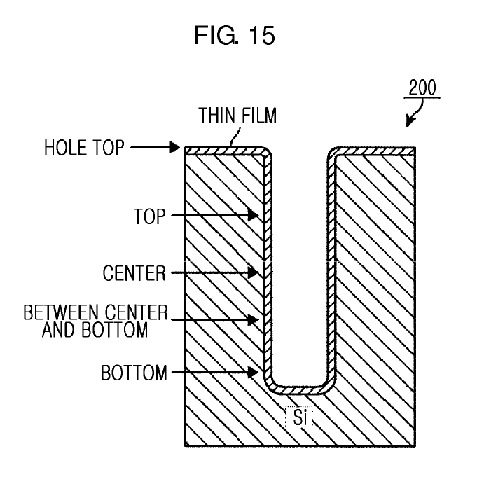

Next, experiments performed to evaluate characteristics of a thin film obtained when a flow rate of a purge gas is higher than a flow rate of each process gas as described above will be described. In these experiments, a small experiment device where a held number of wafers W is 33 (product wafer W: 25 and dummy wafer: 4 at each of the top and bottom) was used. Also, a wafer W having a 3D structure and having a plurality of openings (holes) 200 as shown in FIG. 15 was used. In addition, as described above, the Zr-based gas and the O₃ gas are used, and the purge gas is supplied while switching these gases, and a zirconium oxide film having a target film thickness of 5 nm (50 Å) is formed based on experiment conditions shown below. Also, in the following table, “common” means the same conditions as other experiments.

### Experiment Conditions

| | Comparative | Reference | Present | |
|---|---|---|---|---|
| | Example | Example 1 | Invention | Reference Example 2 |
| Zr- | Common (0.4 ml/min) | | | |
| based | | | | |
| Gas | | | | |
| O₃ Gas | Common | 350 g/Nm³ | Common | |
| Amount | (200 g/Nm³) | | | |
| Purge | 400 sccm | Common | 16 slm | Common |
| Gas | | | | |

| | | |
|---|---|---|
| Process | Common | High-degree Vacuum |
| Pressure | | (50 to 60% of other |
| | | condition) |

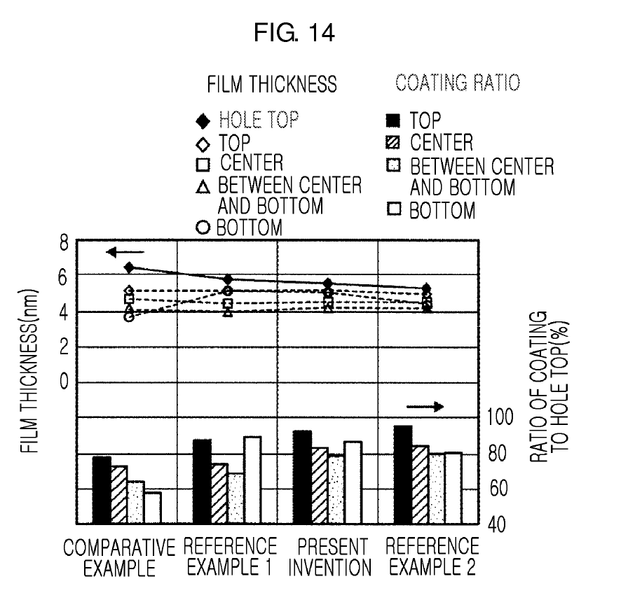

Also, a film thickness of a thin film at the hole top, top, center, between center and bottom, and bottom was measured from the top to the bottom of the opening 200, and a film thickness ratio (step coverage) of the thin film at the bottom when the film thickness of the hole top is 100% was calculated for each experiment condition. The results are shown in the following table and FIG. 14.

| | | Comparative | Reference | Present | Reference |
|---|---|---|---|---|---|
| | | Example | Example 1 | Invention | Example 2 |
| Film | Hole Top | 6.4 | 5.8 | 5.5 | 5.3 |
| Thickness | Top | 4.9 | 5.1 | 5.1 | 5 |
| (nm) | Center | 4.6 | 4.3 | 4.6 | 4.5 |
| | Between | 4.1 | 4 | 4.3 | 4.2 |
| | Center and | | | | |
| | Bottom | | | | |
| | Bottom | 3.7 | 5.2 | 4.8 | 4.3 |
| Step | Top | 77 | 88 | 93 | 94 |
| Coverage | Center | 72 | 74 | 84 | 85 |
| (Film | Between | 64 | 69 | 78 | 79 |
| Thickness | Center and | | | | |
| Ratio (%) | Bottom | | | | |
| to | Bottom | 58 | 90 | 87 | 81 |
| Hole Top) | | | | | |

As a result, in each experiment example, the film thicknesses at the center were almost similar. Since the center is hardly affected by the gas flow rate, it can be determined that the thin films having almost the same film thicknesses are obtained in the experiment conditions in each experiment example. Meanwhile, comparing the comparative example and the present invention, the film thickness at the hole top where a CVD film is specifically easily attached is 0.9 nm thinner in the present invention (5.5 nm) than in the comparative example (6.4 nm), and thus the film thickness at the hole top of the present invention is near to the film thickness (4.6 nm) at the center. In other words, in the present invention, an increment of the film thickness at the hole top to the target film thickness is suppressed by 0.5 nm (5 Å). Accordingly, a process gas is insufficiently replaced in the comparative example, and thus process gases may mix with each other under a process atmosphere (top of the opening 200), thereby generating reaction products in terms of CVD. However, in the present invention, since the purge gas is supplied at a high flow rate of 16 slm, a process gas is satisfactorily replaced and a reaction between reaction gases is suppressed under a process atmosphere, and thus a thin film having similar film thicknesses throughout the top and bottom of the opening 200 can be obtained. Even from calculation results of step coverage, it can be determined that a uniform film thickness is formed along a depth direction of the opening 200 in the present invention.

Also, in the reference example 1, a coating (coverage) property is slightly improved compared to in the comparative example by increasing the flow rate of the O₃ gas. In addition, the reference example 2 has characteristics at the same level as in the present invention. Accordingly, from the results of the reference example 2 and the present invention, it can be said that the reaction between the process gases are suppressed by setting the inside of the reaction pipe 12 to be a high-degree vacuum in the reference example 2, whereas the flow rate of the purge gas is increased instead of setting the inside of the reaction pipe 12 to be a high-degree vacuum in the present invention. Thus, in the present invention, decrease of a film-forming rate due to setting the inside of the reaction pipe 12 to be high-degree vacuum is suppressed and the reaction between the process gases is suppressed.

According to the present invention, the third gas injector for supplying the purge gas is provided along the length direction of the reaction pipe separately from the first gas injector for supplying a process gas, when a film-forming process is performed by sequentially supplying the plurality of types of process gases that react with each other to the plurality of substrates held in a shelf shape in the substrate holding unit. Also, since the slit extended in the length direction is provided on the third gas injector and the purge gas is supplied via the slit when the process gases are switched, the atmosphere for performing the film-forming process can be easily replaced. Accordingly, the reaction between the process gases can be suppressed under an atmosphere, and thus film-forming process having satisfactory coating property throughout the surface of the substrate and having high uniformity can be performed.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A film-forming apparatus which carries a substrate holding unit holding a plurality of substrates in a shelf shape into a vertical reaction pipe around which a heating unit is provided, and performs a film-forming process on the substrates, the film-forming apparatus comprising:
a first gas injector which includes a plurality of gas ejection holes each provided at height locations between the substrates to supply a first process gas to the substrates;
a second gas injector which is provided to be spaced apart from the first gas injector along a circumferential direction of the reaction pipe, is extended along a length direction of the reaction pipe, and includes a plurality of gas ejection holes provided toward the substrates, so as to supply a second process gas that reacts with the first process gas to the substrates;
a third gas injector which is provided to extend along the length direction of the reaction pipe on a location spaced apart from the first gas injector along the circumferential direction of the reaction pipe, and includes a slit for supplying a purge gas from an upper end to a lower end of a holding region of the substrate holding unit holding the substrates;
an exhaust hole which is provided on a side opposite to the first gas injector by interposing the holding region between the first gas injector and the exhaust hole, and for evacuating an atmosphere in the reaction pipe; and
a controller which outputs a control signal to replace the atmosphere in the reaction pipe by sequentially supplying the first process gas and the second process gas into the reaction pipe and supplying the purge gas into the reaction pipe while switching the first and second process gases.

2. The film-forming apparatus of claim 1, wherein a total flow rate of the purge gas supplied from the third gas injector while switching the first and second process gases is 0.05×N to 2.0×N liter/min, wherein N is a held number of substrates.

3. The film-forming apparatus of claim 1, wherein the third gas injector is also used as the second gas injector.

4. The film-forming apparatus of claim 1, wherein the slit is divided into a plurality of numbers along a length direction of the third gas injector, and the divided slit is set longer than a height size from a bottom surface of a k-th substrate to a top surface of a (k+2)th substrate, wherein k is a natural number.

5. The film-forming apparatus of claim 1, wherein the slit is divided into a plurality of numbers along a length direction of the third gas injector, and a length size of the divided slit is set to gradually increase from one of an upper portion or lower portion of the third gas injector to the other.
